(19) United States
(12) Patent Application Publication
(10) Pub. No.: US 2005/0134377 A1
(43) Pub. Date: Jun. 23, 2005

(54) Doherty amplifier

(76) Inventor: Paul W. Dent, Pittsboro, NC (US)

Correspondence Address: COATS & BENNETT, PLLC, P O BOX 5, RALEIGH, NC, 27602, US

(21) Appl. No.: 10/745,213

(22) Filed: Dec. 23, 2003

(51) Int. Cl. H03F 3/68

(52) U.S. Cl. 330/124 R

(57) ABSTRACT

An efficient linear amplifier according to the present invention comprises a primary amplifier for providing power to a load and an auxiliary amplifier for generating an artificial reflection signal. The artificial reflection signal may have a predetermined phase difference as compared to the output signal supplied to the load. The amplifying circuit also includes a coupler connecting the primary amplifier to the load. The coupler includes a load port connected to the load, a primary port connected to an output of the primary amplifier, and an auxiliary port connected to an output of the auxiliary amplifier such that the artificial reflection signal changes an apparent impedance of the load as seen by the primary amplifier.

### BACKGROUND OF THE INVENTION

The present invention relates generally to amplifiers and more particularly to an efficient linear amplifier circuit for amplifying radio frequency (RF) signals of varying amplitude.

Linear power amplifiers are widely used in wireless communication systems to amplify signals transmitted between a base station and a mobile terminal. Because power is at a premium in wireless communication systems, particularly in the mobile terminals, it is desirable for the power amplifiers to provide highly efficient linear amplification. However, because most highly efficient amplifiers operate in saturation, there is a trade-off between high efficiency and linearity.

U.S. Pat. No. 2,210,028 to Doherty describes a vacuum tube amplification system that provides efficient linear amplification for input signals. The Doherty amplifier comprises two vacuum tube amplifiers connected in parallel at their outputs with a quarter wavelength transmission line. Each amplifier is driven with a varying amplitude drive signal. The primary amplifier, which is furthest in line length from an output load, provides an output current proportional to the current of the input drive signal until the primary amplifier reaches saturation.

As the primary amplifier approaches saturation, an auxiliary drive signal begins driving the auxiliary amplifier, which is a quarter wavelength nearer the load than the primary amplifier. Because of the impedance inversion property of the quarter wavelength transmission line, the current provided by the auxiliary amplifier reduces the apparent impedance of the load as seen by the primary amplifier. As a result, the primary amplifier can supply more current, and therefore, can supply more power to the load. For example, assume the primary amplifier alone provides Pₘₐₓ/4 of output power at saturation. Further, assume that the auxiliary amplifier can also provide up to Pₘₐₓ/4 of output power. According to the Doherty amplification system, driving both amplifiers into saturation causes the total output power at the load to increase from Pₘₐₓ/4 to Pₘₐₓ.

The efficiency curve of a Doherty amplification system has two efficiency peaks. Assuming the primary amplifier provides Pₘₐₓ/4 of output power at saturation, the efficiency peaks occur at Pₘₐₓ/4, when the first amplifier alone saturates, and again at Pₘₐₓ, when both amplifiers saturate. Further, the efficiency is maintained at a high value between the two efficiency peaks. In contrast, the efficiency of a conventional power amplifier at Pₘₐₓ/4 is half the efficiency provided by the same power amplifier at Pₘₐₓ. Consequently, the Doherty amplification system significantly improves the average efficiency associated with linearly amplifying signals of varying amplitude.

Another prior art amplification system is described by Chireix in Proc. IRE, Vol. 23 No. 11 (1935), pages 1370-1392, entitled “High Power Outphasing Modulation.” Chireix describes a transmitter that provides a modulated amplitude output signal by combining two constant output amplitude amplifiers with a variable phase difference such that the amplifiers may be varied in relative phase from additive to subtractive. Unlike the Doherty amplification system, the Chireix system relies on the primary and auxiliary amplifiers being out-of-phase.

U.S. Pat. No. 6,133,788 to Applicant entitled “Hybrid Chireix/Doherty Amplifiers and Methods” discloses a combination of the techniques of Chireix and Doherty. According to the '788 patent, an advantageous way to construct a Doherty amplifier using modern technology is to use a digital signal processor to generate two quadrature modulating waveforms with two separate quadrature modulators in order to form out-of-phase amplifier drive signals for the primary and auxiliary amplifiers. The '788 patent also teaches that efficient linear amplification may be performed using two constant amplitude amplifiers as compared to the two linear amplifiers used in the Doherty amplification system.

Another variation is described in a CIP to the above '788 patent, now issued as U.S. Pat. No. 6,359,506. According to the '506 patent, the primary amplifier operates in saturation, so that it produces a constant amplitude output voltage. The auxiliary amplifier is driven to generate an amplitude modulated signal output. By coupling the primary and auxiliary amplifiers through the quarter wavelength transmission line, the drive signal of the auxiliary amplifier modulates the effective load impedance seen by the primary amplifier, and therefore, provides efficient amplifier coupling.

### SUMMARY OF THE INVENTION

The present invention comprises a method and apparatus to provide efficient linear amplification of radio frequency (RF) signals. An amplifying circuit according to an exemplary embodiment of the present invention comprises a primary amplifier for providing power to a load and an auxiliary amplifier for generating an artificial reflection signal. The artificial reflection signal has a predetermined phase difference as compared to the output signal supplied to the load. The amplifying circuit also comprises a coupler connecting the primary amplifier to the load. The coupler includes a load port connected to the load, a primary port connected to an output of the primary amplifier, and an auxiliary port connected to an output of the auxiliary amplifier such that the artificial reflection signal changes an apparent impedance of the load as seen by the primary amplifier. According to exemplary embodiments of the present invention, the coupler may be a circulator or a quadrature coupler.

The present invention may be implemented by supplying power to a load using a primary amplifier, generating an artificial reflection signal with an auxiliary amplifier, and connecting the primary amplifier to the load with a coupler. The coupler connects the primary amplifier to the load by connecting a load port to the load, connecting a primary port to an output of the primary amplifier, and connecting an auxiliary port to an output of the auxiliary amplifier such that the artificial reflection signal changes an apparent impedance of the load as seen by the primary amplifier at the primary port.

### BRIEF DESCRIPTION OF THE DRAWINGS

FIG. 1 illustrates an exemplary amplifier circuit according to the present invention.

FIG. 2 illustrates a first exemplary embodiment of the amplifier circuit of FIG. 1.

FIG. 3A illustrates an exemplary efficiency plot where a =0.5 for the amplifier circuit of FIG. 2.

FIG. 3B illustrates an exemplary amplifier drive signal plot associated with the exemplary efficiency plot of FIG. 3A.

FIG. 4A illustrates another exemplary efficiency plot where a =1 for the amplifier circuit of FIG. 2.

FIG. 4B illustrates an exemplary amplifier drive signal plot associated with the exemplary efficiency plot of FIG. 4A.

FIG. 4C illustrates an exemplary drive circuit for the amplifier circuit of FIG. 2.

FIG. 5A illustrates another exemplary “Buck and Boost” efficiency plot for the amplifier circuit of FIG. 2.

FIG. 5B illustrates an exemplary amplifier drive signal plot associated with the exemplary efficiency plot of FIG. 5A.

FIG. 6 illustrates a second exemplary embodiment of the amplifier circuit of FIG. 1.

FIG. 7 illustrates an exemplary amplifier drive signal plot for the amplifier circuit of FIG. 6.

FIG. 8 illustrates an exemplary auxiliary amplifier configuration for the amplifier circuit of FIG. 2.

FIG. 9 illustrates an exemplary auxiliary amplifier configuration for the amplifier circuit of FIG. 6.

FIG. 10 illustrates an exemplary signal generator for the auxiliary amplifier of FIG. 1.

FIG. 11 illustrates an exemplary RF signal generator for the auxiliary amplifier of FIG. 1.

FIG. 12 illustrates an exemplary transceiver that uses the amplifier circuit of FIG. 1.

### DETAILED DESCRIPTION OF THE INVENTION

In each of the above described amplification systems, the auxiliary amplifier is directly connected to the output of the primary amplifier, even when the auxiliary amplifier does not contribute any power to the load. The auxiliary amplifier increases the total losses associated with the amplifier circuit. To minimize these losses, the auxiliary amplifier may be tuned to present a high output impedance at the junction between the primary and auxiliary amplifiers so that the auxiliary amplifier looks like an open circuit to the primary amplifier when the auxiliary amplifier is not contributing any power to the load. However, when used in systems operating at microwave frequencies, the high output impedance may be difficult to achieve.

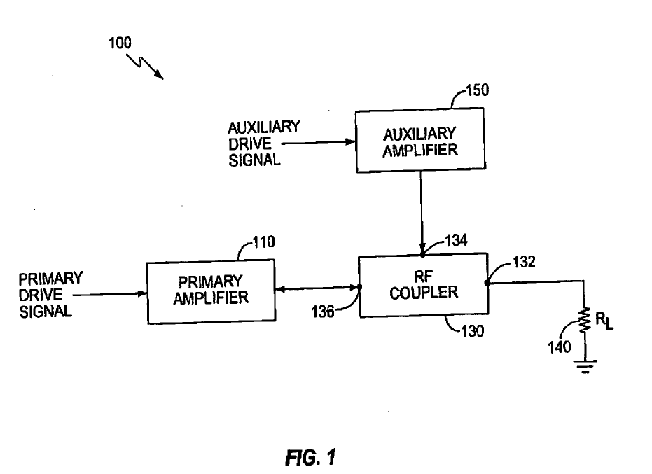

FIG. 1 illustrates a block diagram for an exemplary amplifier circuit 100 according to the present invention. Amplifier circuit 100 is applicable to any wireless transmitter, such as the base station and/or mobile terminal transmitter. The term “mobile terminal” may include a cellular radiotelephone with or without a multi-line display; a Personal Communication System (PCS) terminal that may combine a cellular radiotelephone with data processing, facsimile, and data communications capabilities; a Personal Digital Assistant (PDA) that can include a radiotelephone, pager, Internet/intranet access, web browser, organizer, calendar, and/or a global positioning system (GPS) receiver; and a conventional laptop and/or palmtop receiver or other appliance that includes a radiotelephone transceiver. Mobile terminals may also be referred to as “pervasive computing” devices.

Amplifier circuit 100 includes a primary amplifier 110, an RF coupler 130, a load 140, and an auxiliary amplifier 150. RF coupler 130 connects primary amplifier 110 to the load 140 and has at least three ports: a load port 132, an auxiliary port 134, and a primary port 136. The load 140 connects to the RF coupler 130 at the load port 132, the output of the auxiliary amplifier 150 connects to the RF coupler 130 at the auxiliary port 134, and the output of the primary amplifier 110 connects to the RF coupler 130 at the primary port 136.

Initially, auxiliary amplifier 150 does not provide any current to load 140, and therefore, is effectively disabled while primary amplifier 110 provides power to the load 140. Primary amplifier 110 provides power up to a saturation output power level to the load 140. As the primary amplifier 1O approaches saturation, the auxiliary amplifier 150 is enabled and injects an artificial reflection signal into the output of primary amplifier 110 via the RF coupler 130. As with the Doherty amplifier, the reflection signal changes the apparent impedance of the load 140 as seen by primary amplifier 1 10, which enables the primary amplifier 110 to provide more current, and therefore, more power to the load 140. However, unlike the Doherty amplifier, auxiliary amplifier 150 is not directly connected to load 140, and therefore, does not contribute to the overall losses associated with the amplifier circuit 100. Further, because auxiliary amplifier 150 is not directly connected to load 140, the phase of the artificial reflection signal input into the RF coupler 130 may differ by a predetermined phase difference from the phase of the output signal supplied to the load 140.

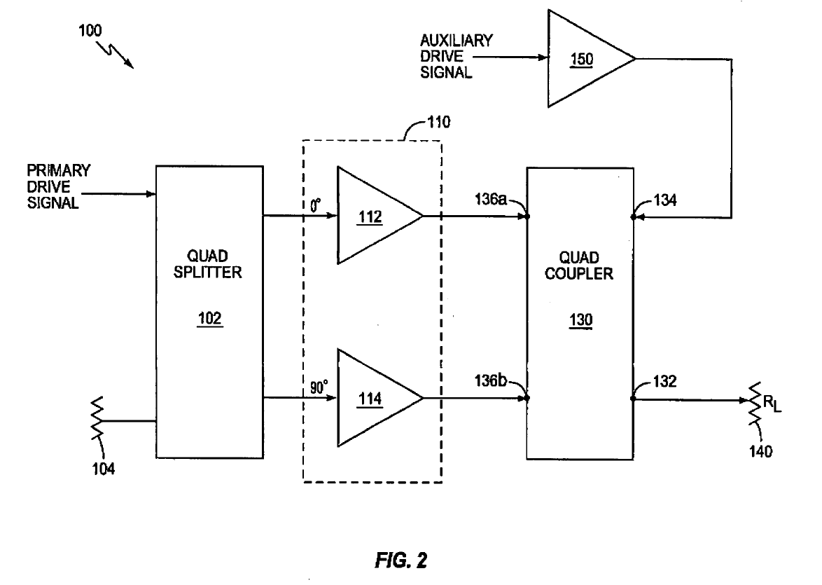

FIG. 2 illustrates an exemplary embodiment of the amplifier circuit 100 of FIG. 1. According to the exemplary embodiment, primary amplifier 10 comprises a first primary amplifier 112 and a second primary amplifier 114 driven in quadrature by a quadrature splitter 102. RF coupler 130 comprises a quadrature coupler 130, where primary port 136 comprises a first primary port 136a and a second primary port 136b. The first and second primary ports 136a, 136b couple the outputs of the first and second primary amplifiers 112, 114 to load 140.

As shown in FIG. 2, a primary drive signal input to a first input port of quadrature splitter 102 is equally split between two output ports of the quadrature splitter 102. Therefore, the primary drive signal is equally split between the first and second primary amplifiers 112, 114. However, due to the properties of the quadrature splitter 102, there is a 90° phase difference between the signal input to the first primary amplifier 112 and the signal input to the second primary amplifier 114. For simplicity, it is assumed that the phase of the primary drive signal is arbitrarily set to 0°. Therefore, the phase of the signal input to first primary amplifier 112 is 0°, while the phase of the signal input to second primary amplifier 114 is −90°. A load 104 is connected to the second input of quadrature splitter 102 to absorb any signals present at this port. However, it will be appreciated by those skilled in the art that a signal may be input to the second input port of quadrature splitter 102. As with the first input port, a signal input to the second input port of quadrature splitter 102 is equally split between the inputs to the first and second primary amplifiers 112, 114. However, the phasing of the signal input to the second input port is reversed from the phasing of the signal input to the first input port, e.g., 0° at the input to the second primary amplifier 114 and −90° at the input to the first primary amplifier 112.

Quadrature coupler 130 behaves in exactly the same manner as quadrature splitter 102. Therefore, the signal from the first primary amplifier 112 and the signal from the second primary amplifier 114 both arrive at the load with the same phase, and add constructively at the load 140. Further, the signal from the first primary amplifier 112 and the signal from the second primary amplifier 114 arrive 180° out of phase at auxiliary port 134, and therefore, add destructively at the auxiliary port 134.

As discussed above, auxiliary amplifier 150 is effectively disabled while primary amplifier 110 operates below its saturation point. However, as primary amplifiers 112, 114 approach saturation, the auxiliary amplifier 150 is enabled. The enabled auxiliary amplifier 150 generates an artificial reflection signal with a phasing of −180°, based on the auxiliary drive signal, and injects the artificial reflection signal into auxiliary port 134. The artificial reflection signal is split at first and second primary ports 136a, 136b to produce an artificial reflection signal of phase −180° traveling backwards into the output port of the first primary amplifier 112, and an artificial reflection signal of phase −270 degrees traveling backwards into the output port of the second primary amplifier 114. The phase of these artificial reflection signals are both 180° offset from the phase of the output signals generated by the respective amplifiers 112, 114. Therefore, the artificial reflection signals appear to primary amplifiers 112, 114 as a load impedance mismatch to the low impedance side. Because of this “apparent” change in load impedance, the primary amplifiers 112, 114 increase their output current and deliver more power to the load 140.

It will be appreciated that, whatever the line length between first and second primary amplifiers 112, 114 and ports 136a, 136b, and whatever the line length between auxiliary amplifier 150 and auxiliary port 134, a suitable phasing of the auxiliary drive signal may be found to produce the above situation. Therefore, when auxiliary amplifier 150 has an appropriately phased drive signal, auxiliary amplifier 150 can change the apparent impedance of the load 140 as seen by primary amplifiers 112, 114, and therefore, increase the output power provided by amplifier circuit 100 to load 140.

To illustrate the above embodiment, consider the following example. Assume that auxiliary amplifier 150 produces an artificial reflection signal with an output voltage having a wave amplitude of \sqrt{2}aVₒwhere “a” is an auxiliary constant that may be set to any desired number to produce a desired power output from auxiliary amplifier 150, as discussed further below. Further, assume that primary amplifiers 112, 114 are each modeled as voltage sources of wave amplitude Vₒ when saturated. When the auxiliary drive signal begins driving auxiliary amplifier 150, quadrature coupler 130 splits the artificial reflection signal generated by auxiliary amplifier 150 into equal waves, each having an amplitude aVₒ, traveling backwards into the output of the primary amplifiers 112, 114. The artificial reflection signals reach the outputs of the primary amplifiers 112, 114 with a phase 180° offset from the phase of the amplifier output voltages. Due to conservation of energy, the sum of the forward voltage waves (from the primary amplifiers 112, 114) and the reverse voltage waves (from the auxiliary amplifier 150) at the outputs of the primary amplifiers 112, 114 equals Vₒ. Therefore, at the outputs of the primary amplifiers 112, 114, the forward voltage wave amplitudes are (1+a) Vₒ and the reverse voltage wave amplitudes due to the artificial reflection signals are -aVₒ.

As a result, the voltage reflection coefficient “r” is -a/(l+a), and the load impedance seen by primary amplifiers 112, 114 is R_{L}(1+r)/(1−r) =R_{L}(1+2a). The current output by primary amplifiers 112, 114 into load 140 may therefore be represented by (1 +2a) Vₒ/R_{L}. Because the current normally produced by each primary amplifier 112, 114 alone is Vₒ/R_{L}, the current produced by each primary amplifier 112, 114, as influenced by auxiliary amplifier 150, has increased by a factor of 1+2a. The resulting output power into the load from each primary amplifier 112, 114 is therefore (1 +2a) Vₒ²/R_{L}, which is also higher than the power provided by primary amplifiers 112, 114 alone by the factor 1+2a.

The forward voltage waves from primary amplifiers 112, 114 combine at the load 140 via quadrature coupler 130 to produce a voltage wave amplitude into load 140 of 29 \sqrt{2}(1+a)·Vₒ. When combined with the voltage wave amplitude from auxiliary amplifier 150 (\sqrt{2}aVₒ), the delivered power into load 140 is 2(1+a) ²Vₒ²/R_{L}. It may be verified that this delivered power is the sum of the powers (1 +2a) Vₒ²/R_{L} from each of the primary amplifiers 112, 114 and the power 2a ²Vₒ²/R_{L} from auxiliary amplifier 150. Thus, all the power generated by the three amplifiers 112, 114, 150 is transferred to load 140.

For example, suppose each of primary amplifiers 112, 114 saturate at a power level of Pₘₐₓ, given by:

$${P}_{max} = \frac{{V}_{o}^{2}}{{R}_{L}} .$$

Further, suppose auxiliary amplifier 150 is designed to saturate at a level of Pₘₐₓ/2 (by choosing a =0.5). When auxiliary amplifier 150 is disabled, the power output into load 140 is simply 2Pₘₐₓ. However, when auxiliary amplifier 150 is enabled and saturated, the power output into the load is 2(1+a)²Pₘₐₓ₌4.5Pₘₐₓ. By generating a power level varying from zero to Pₘₐₓ/ 2, auxiliary amplifier 150 causes the total output power at the load 140 to vary from 2Pₘₐₓ to 4.5Pₘₐₓ, with the primary amplifiers 112, 114 generating the majority of the power at maximum saturated efficiency.

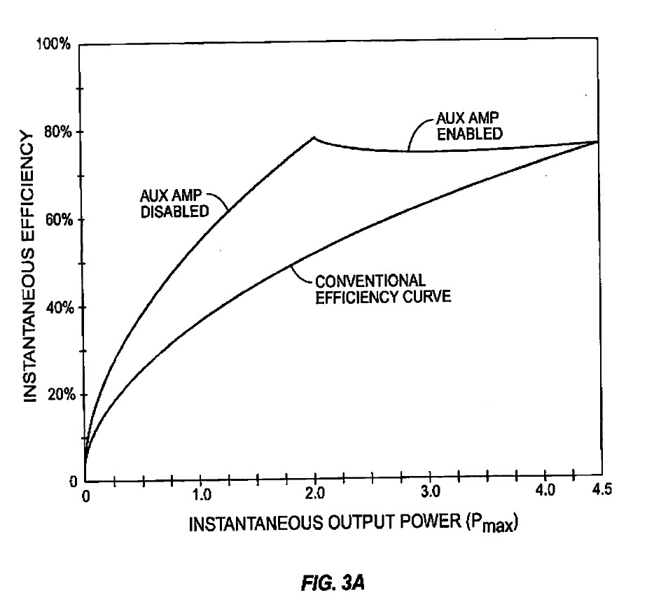

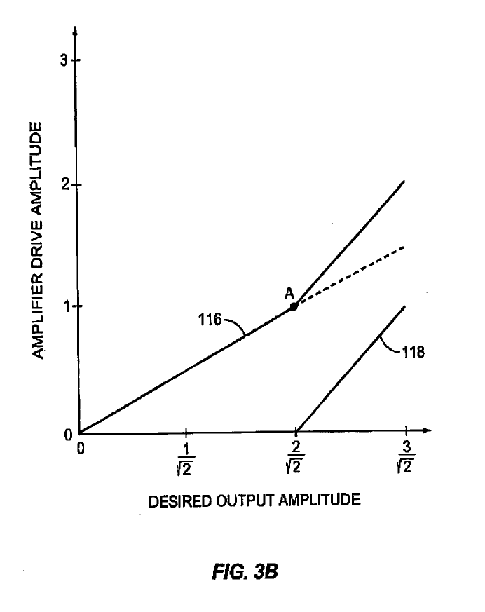

FIG. 3A plots the efficiency vs. instantaneous output power of the amplifier circuit 100 (when a =0.5) over the instantaneous output power range of 0 to 4.5Pₘₐₓ. For comparison, FIG. 3A also includes the maximum theoretical efficiency of a conventional class-B amplifier. The efficiency of the conventional class-B amplifier is computed assuming ideal class-B amplifier operation. Those skilled in the art will appreciate that while practical losses will reduce these efficiencies, the relative advantage of the invention is maintained.

In FIG. 3A, power outputs below 2Pₘₐₓ are obtained using primary amplifiers 112, 114 below saturation, with auxiliary amplifier 150 disabled. Because auxiliary amplifier 150 is disabled, the efficiency curve from power level 0 to 2Pₘₐₓ exhibits the class-B efficiency curve shape, with a peak at 2Pₘₐₓ of instantaneous output power. After auxiliary amplifier 150 is enabled, the efficiency peaks again at a power level of 4.5Pₘₐₓ, when primary amplifiers 112, 114 each operate with an output power of 2Pₘₐₓ, and auxiliary amplifier 150 operates with a saturated output power of 0.5Pₘₐₓ. Between the levels of 2Pₘₐₓ and 4.5Pₘₐₓ, auxiliary amplifier 150 operates below saturation on its own efficiency versus power output curve. However, because auxiliary amplifier 150 contributes only a small proportion of the output power, the overall efficiency of the amplifier circuit 100 drops only slightly while auxiliary amplifier 150 is unsaturated.

Above their saturation points, primary amplifiers 112, 114 generate an output current proportional to 1 +2a; the output current of auxiliary amplifier 150 increases linearly with “a” above the saturation point of the primary amplifiers 112, 114. As a result, the output amplitude of the entire amplifier circuit 100 increases proportionally to 1+a, as described above. Because drive signals of linear amplifiers track the output signals of the linear amplifiers, the primary and auxiliary drive signals also increase proportionally to 1 +2a and a, respectively.

FIG. 3B plots exemplary primary and auxiliary amplifier drive signals used to operate the amplifier circuit 100 of FIG. 2 as a function of a desired output amplitude for the case of a =0.5. Before primary amplifiers 112, 114 reach saturation, the ratio of the amplifier drive amplitude to the desired output amplitude is \sqrt{2/2}. Once the primary amplifiers 112, 114 reach saturation (at point A in FIG. 3B), auxiliary amplifier 150 is enabled and the drive current changes in proportion to the new output current provided by the amplifier circuit 100. Once auxiliary amplifier 150 is enabled, it can be shown that the ratio of the amplifier drive amplitude to the desired output amplitude is \sqrt{2}.

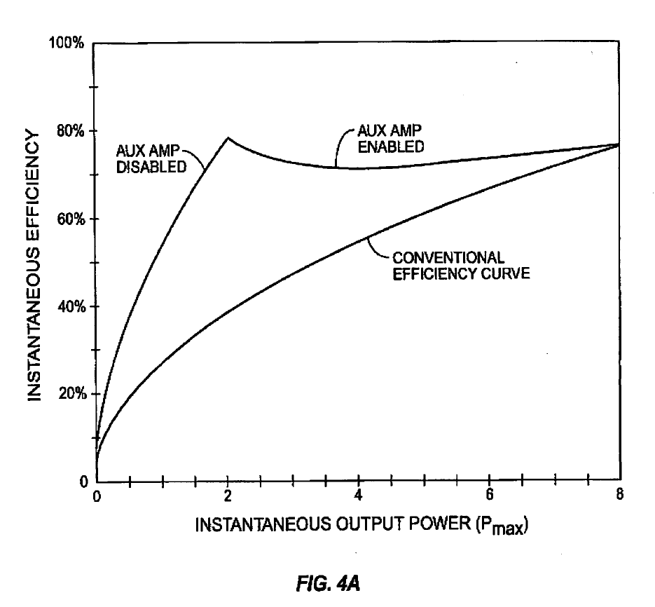

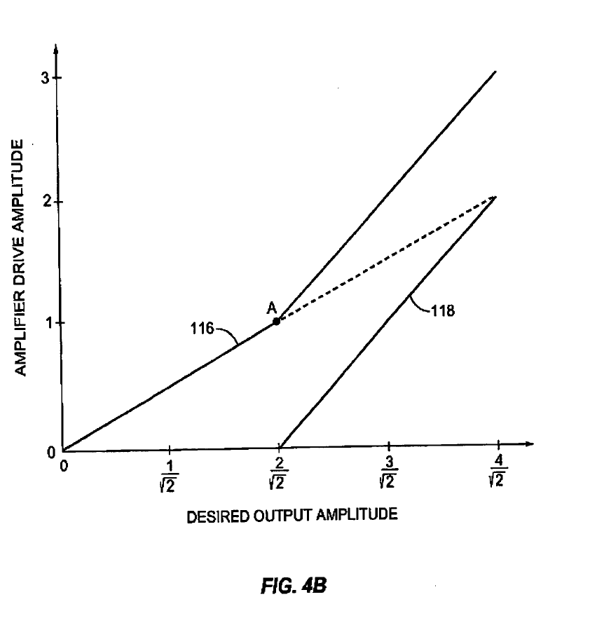

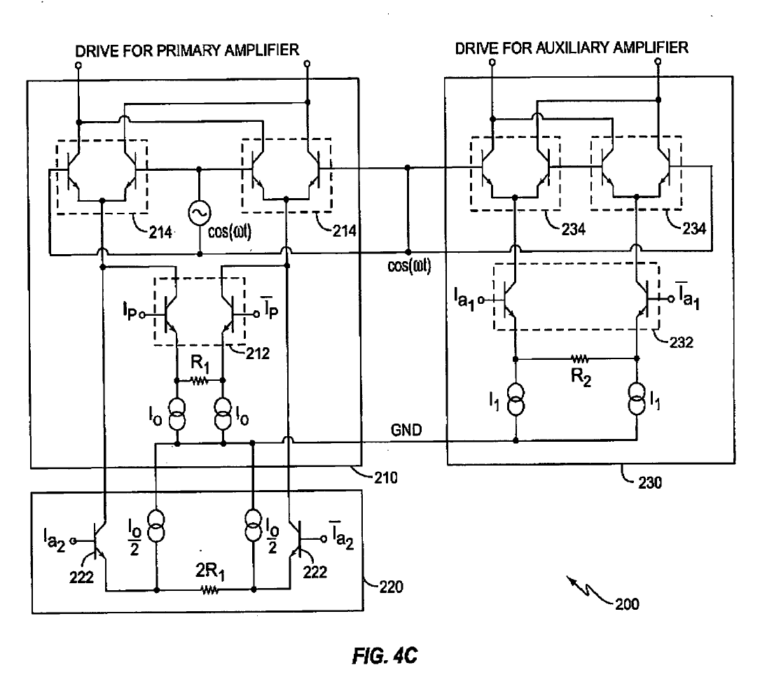

The efficiency associated with the amplifier circuit 100 may be altered to suit particular applications by choosing the maximum value, aₘₐₓ, of the scaling factor “a”. If aₘₐₓ₌1, for example, auxiliary amplifier 150 has a saturated output power twice that of each of primary amplifiers 112, 114 into a load 140. The resulting efficiency curve, shown in FIG. 4A, exhibits a first maximum efficiency at a power output of 2Pₘₐₓ, where Pₘₐₓ is the saturation power level of each of primary amplifiers 112, 114 into load 140. After auxiliary amplifier 150 is enabled, the apparent impedance of the load 140 as seen by primary amplifiers 112, 114 decreases due to the artificial reflection signal. When saturated, auxiliary amplifier 150 provides 2Pₘₐₓ and each primary amplifier 112, 114 provides 3Pₘₐₓ to load 140. Therefore, a second maximum efficiency peak occurs at 8Pₘₐₓ.

The amplifier circuit 100 used to generate the efficiency curve of FIG. 4A (aₘₐₓ₌1) operates with substantially maximum efficiency over a 6dB range of instantaneous output power. This amplifier circuit 100 is suitable for efficient linear amplification of signals with a 6dB peak to mean ratio, or of signals that may be clipped at 6dB above the root mean square value (rms). For example, the sum of many signals is amplified in cellular base station transmitters using code division multiple access (CDMA). The sum of these signals has a Gaussian amplitude distribution, according to the Central Limit Theorem. However, the Gaussian distribution has theoretically infinite peak values, which are almost never reached. The probability of a Gaussian signal exceeding its rms value by 6dB is sufficiently small that values greater than this may be limited to that value while producing only a tolerable increase in out-of-band spectral energy. In that case, the amplifier circuit 100 corresponding to the efficiency curve of FIG. 4A may be operated at an rms level coincident with the maximum efficiency point at output power 2Pₘₐₓ.

FIG. 4B illustrates the amplitude drive signals vs. the desired output amplitude for aₘₐₓ₌1. As shown in FIG. 4A, the combined output power at the load 140 of the primary amplifiers 112, 114 when saturated is 2Pₘₐₓ before auxiliary amplifier 150 is activated, which corresponds to a desired output amplitude of \sqrt{2} units. Thus, for each of primary amplifiers 112, 114, the amplifier drive amplitude ranges linearly from 0 to 1 unit for the desired output amplitude range of 0 to \sqrt{2} units, as shown in FIG. 4B.

As the power output is increased beyond 2Pₘₐₓ, auxiliary amplifier 150 is enabled. As with the primary amplifiers 112, 114, the output power associated with auxiliary amplifier 150 for aₘₐₓ₌1 ranges from 0 to 2Pₘₐₓ and requires an amplifier drive signal ranging linearly from 0 to 2 units. Because gain is an arbitrary scaling, the input drive amplitude of the auxiliary amplifier 150 would also range from 0 to 2 units if the gain of the auxiliary amplifier 150 was 3dB lower than the gain of the primary amplifiers 112, 114. Therefore, the amplifier drive signal for amplifier circuit 100 may be the result of generating a linearly proportional drive signal for primary amplifiers 112, 114 over the entire range, ending at 2 units of amplifier drive amplitude, and adding some appropriate fraction, e.g., 0.5, of the auxiliary drive signal when auxiliary amplifier 150 is enabled.

FIG. 4C provides an exemplary drive circuit 200 for achieving the above-described amplifier drive signal when aₘₐₓ₌1. FIG. 4C only shows the I-parts of the drive circuit 200 for generating the primary and auxiliary amplifier drive signals. Apart from being fed with balanced Q signals, the Q-parts of the drive circuit 200 would be identical. The I, Q outputs would be connected in parallel to generate the primary and auxiliary amplifier drive signals.

The exemplary circuit of FIG. 4C comprises a primary modulator 210, a supplemental circuit 220, and an auxiliary modulator 230. Primary modulator 210 is a Gilbert-cell type balanced modulator comprising a principal transistor pair 212, driven by the primary signal Iₚ and its inverse \overline{I}ₚ, and two switching transistor pairs 214, driven by a cosine carrier signal. The emitter voltages generated by principal transistor pair 212 appear across resistor R₁, causing an imbalance in the collector currents of principal transistor pair 212. Switching transistor pairs 214 switch the imbalanced collector currents such that the imbalanced collector currents are modulated by cos(ωt) to produce the In-phase part (or real part) of the primary drive signal.

Similarly, auxiliary modulator 230 is a Gilbert-cell type balanced modulator comprising a principal transistor pair 232, driven by the auxiliary signal Iₐ₁ and its inverse \overline{I}ₐ₁,an and two switching transistor pairs 234 driven by the cosine carrier signal. Switching transistor pairs 234 modulate the imbalanced collector currents from principal transistors 232 to generate the In-phase (or real) part of the auxiliary drive signal.

Iₐ₁and \overline{I}ₐ₁ have zero amplitude until primary amplifier 110 approaches saturation. As primary amplifier 110 approaches saturation, the amplitude of Iₐ₁ begins increasing, causing auxiliary amplifier 150 to boost the output capability of the primary amplifier 110, as described above. As shown in FIG. 4B, after auxiliary amplifier 150 is enabled primary amplifier 110 requires a drive signal that rises 50% faster. This additional rise in the primary drive signal is implemented in the drive circuit 200 of FIG. 4C by supplemental circuit 220. Supplemental circuit 220 includes a supplemental principal transistor pair 222 driven by auxiliary drive signals Iₐ₂ and its inverse \overline{I}ₐ₂. Note, the auxiliary signal Iₐ₂ has been distinguished by a suffix “2” when applied to supplemental transistor pair 222, as opposed to a suffix “1” when applied to auxiliary modulator 230 because the contribution of Iₐ₂ to the primary amplifier 110 may have to be independently phased as compared to Iₐ₁, for the auxiliary amplifier 150 to obtain the proper phase relationships.

Assuming the amplitude of the primary drive signal rises linearly over the range 0 to 2 while the primary amplifier 110 actually requires a peak drive amplitude of 3, and assuming the auxiliary drive signals also peak at an amplitude of 2, the contribution from supplemental principal transistors is scaled by one half and added to the contribution from principal transistors 212. Thus, the emitter resistance for supplemental transistor pair 222 is double the resistance of the principal transistor pair 212. The current sources in supplemental circuit 220 may also be scaled down from Iₒ, to Iₒ/2 to conserve current. As a result, the exemplary drive circuit 200 generates the primary and auxiliary drive currents shown in FIG. 4B.

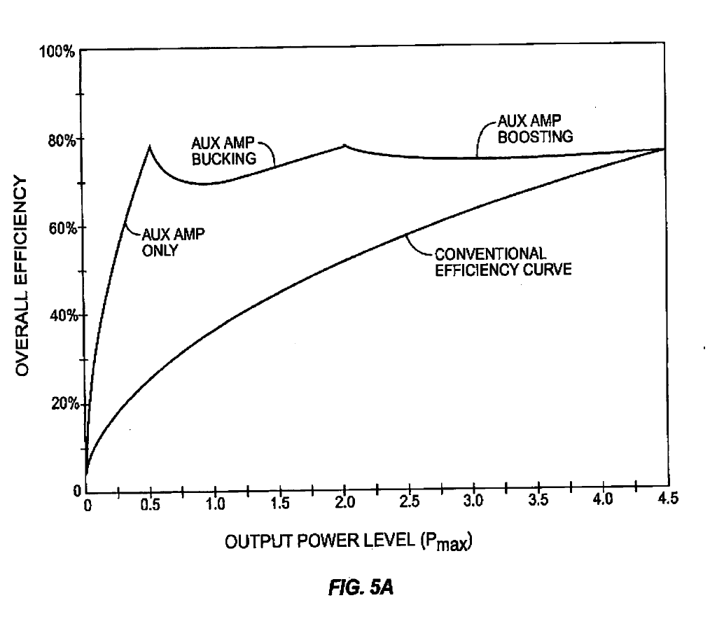

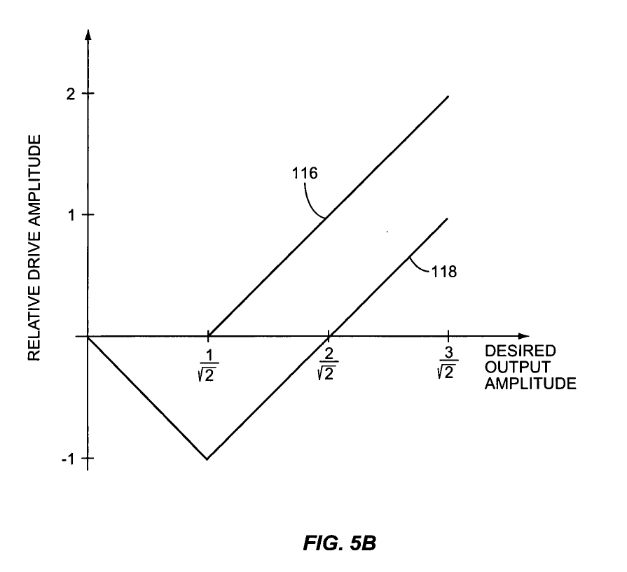

Turning now to FIG. 5A, an alternate embodiment that improves the efficiency of the amplifier circuit 100 below 2Pₘₐₓ, where primary amplifiers 112, 114 are operating unsaturated, will be described. When primary amplifiers 112, 114 operate below saturation, auxiliary amplifier 150 may be used to reduce the output power (instead of increasing it) by inverting the auxiliary constant “a”. By switching the phase of auxiliary amplifier 150 by 180°, the sign of the constant “a” is inverted. As a result, the reverse voltage wave amplitude reaching the output ports of primary amplifiers 112, 114 is “+a” instead of “−a,” and the forward voltage wave amplitude is 1− a instead of 1+a. Therefore, the reflection coefficient, “r,” is a/(1−a) and the apparent impedance of load 140 as seen by the primary amplifiers 112, 114 is R_{L}/(1−2a). When a =0.5, the apparent impedance of load 140 as seen by primary amplifiers 112, 114 is infinite. As a result, while primary amplifiers 112, 114, in principle, still operate in voltage saturation, no output current is provided to the load. Because the primary amplifiers 112, 114 do not provide any output current to the load 140, the output current provided by auxiliary amplifier 150 is the only contribution to the load 150. Thus, a third point on the efficiency curve exists at the saturation power level of auxiliary amplifier 150, i.e., 0.5Pₘₐₓ when a =0.5. Providing that the outputs of primary amplifiers 112, 114 are effectively open circuits, the efficiency curve below 0.5Pₘₐₓ is completed by modulating auxiliary amplifier 150 down to zero.

The modulation of auxiliary amplifier 150 used to obtain the efficiency curve at output powers below 0.5Pₘₐₓ is, however, non-linear; auxiliary amplifier 150 is therefore amplitude modulated in the range a =0 to a =0.5. Primary amplifiers 112, 114 are enabled just as auxiliary amplifier 150 reaches saturation. At this point, auxiliary amplifier 150 is modulated downwards from a =0.5 to 0, causing now-driven primary amplifiers 112, 114 to contribute to the total power at the load 140 between the power range of 0.5Pₘₐₓ to 2Pₘₐₓ. Auxiliary amplifier 150 is then linearly amplitude modulated in the negative (−a) direction, which completes the power range from 2Pₘₐₓ to 4.5Pₘₐₓ. FIG. 5A shows the resulting efficiency curve obtained by this “Buck and Boost” mode of operation. The higher efficiencies at the lower power levels are, however, only obtained at the expense of some complexity in generating the amplifier drive signals (shown in FIG. 5B), as compared to amplifier drive signals for the “Boost only” cases of FIGS. 3B and 4B, for which the drive signals are more straightforward to generate.

As explained above for the a =0.5 case, reversing the phase of the auxiliary amplifier allows the power to be modulated lower than 2Pₘₐₓ while keeping primary amplifiers 112, 114 saturated. When a =1 however, an interesting effect occurs. Assume that primary amplifiers 112, 114 are built with bi-directional devices that can return current to a battery by acting as synchronous rectifiers, as explained further in U.S. Pat. Nos. 5,930,128; 6,097,615; 6,181,199; 6,201,452; 6,285,251; 6,311,046; 6,359,506; 6,369,651 and 6,411,655 to Applicant, which are hereby incorporated by reference herein. At maximum inverse contribution from auxiliary amplifier 150 with a =1, primary amplifiers 112, 114 receive the incident energy from auxiliary amplifier 150, synchronously rectify it, and return the energy as DC current to the battery. At this exact level, the “rectifier” input impedance appears to be R_{L}, so no energy is reflected from primary amplifiers 112, 114, and the output power to the load 140 is zero, despite auxiliary amplifier 150 generating power.

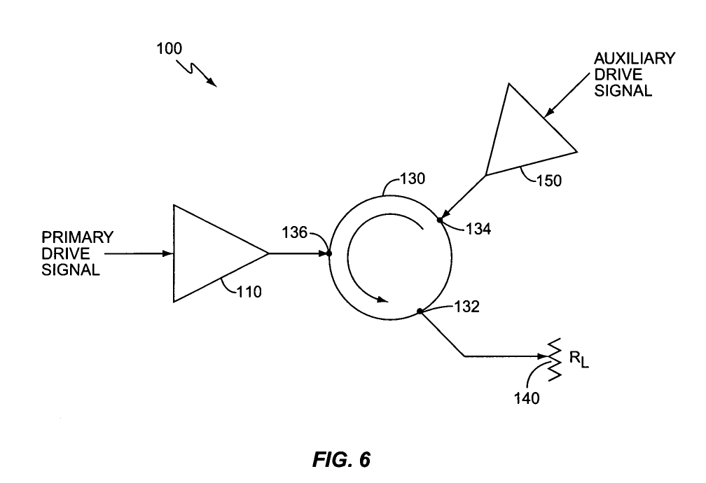

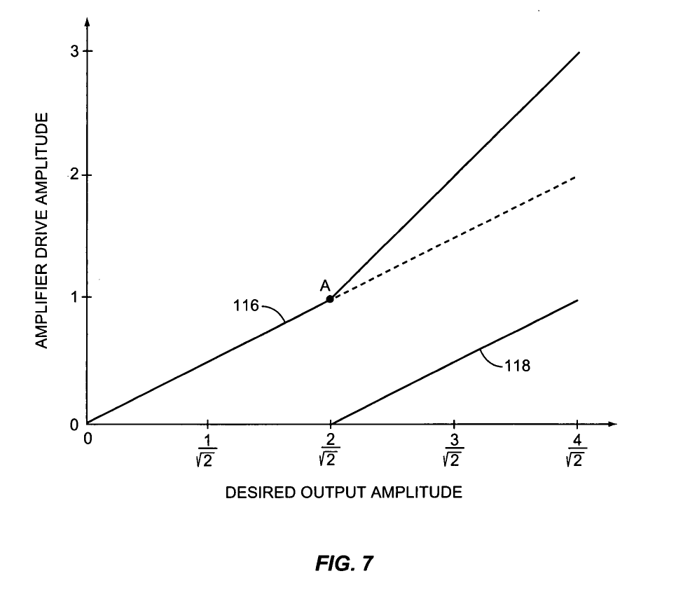

Referring now to FIG. 6, another embodiment of the present invention will be described. In the embodiment of FIG. 6, a circulator 130 replaces the quadrature coupler 130. In the circulator configuration, a single primary amplifier 110 feeds its output through circulator 130 to load 140. When the primary amplifier 110 is driven, it produces an output power between 0 and the saturated power level of Pₘₐₓ=Vₒ²/R_{L}. Beyond the saturation point, primary amplifier 110 remains saturated while auxiliary amplifier 150 is enabled and outputs an artificial reflectance signal with a voltage wave amplitude of a Vₒ to the auxiliary port 134 of circulator 130. The circulator 130 transfers the artificial reflectance signal to the primary port 136, where it travels backwards into the output of the primary amplifier 110 looking like a reflected wave from load 140. With the proper phasing, the artificial reflected signal changes the apparent impedance of the load 140 as seen by primary amplifier 110 from R_{L} to R_{L}/(1+2a). For example, when a =1, i.e. auxiliary amplifier 150 has the same power level as primary amplifier 110, and the impedance of the load 140 as seen by the primary amplifier 110 is R_{L}/3. Due to the artificial reflection signal, primary amplifier 110 contributes three times its normal saturated output power level of Pₘₐₓ into the load 140 while auxiliary amplifier 150 contributes Pₘₐₓ, resulting in a total of 4Pₘₐₓ at the load 140. When suitably scaled, the efficiency curve of this arrangement is exactly the same as FIG. 4A. The drive amplitudes for this embodiment are shown in FIG. 7. It will be appreciated by those skilled in the art that, after some slight modifications, the above described efficiency curves and drive signals are also applicable to the circulator configuration.

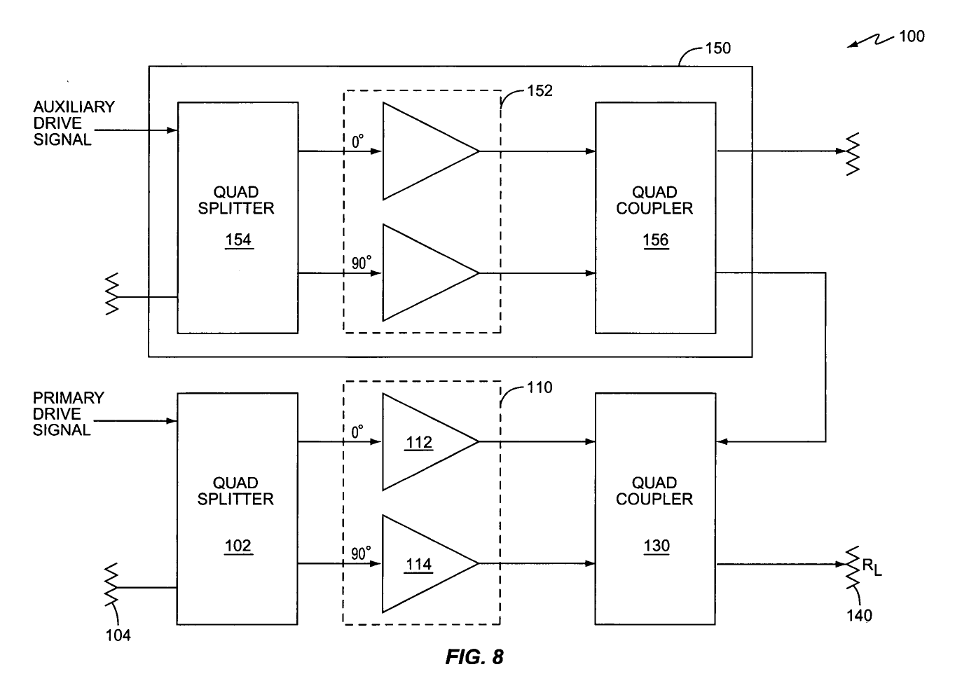

While FIG. 2 shows auxiliary amplifier 150 as a single amplifier, there are a number of ways to construct auxiliary amplifier 150 according to the present invention. For example, auxiliary amplifier 150 may, if desired, be constructed identically to the primary amplifier 110, using a pair of quadrature coupled amplifiers 152 in place of the single auxiliary amplifier of FIG. 2, as shown in FIG. 8. In this scenario, the juxtaposition of the auxiliary amplifier 150 and the primary amplifiers 112, 114 is completely symmetrical. Therefore, either may serve as the auxiliary or the primary amplifier. For example, if a signal input is fed into the unused input port of the auxiliary amplifier input quadrature splitter 154, the amplified output appears at the terminated port of the auxiliary amplifier output coupler 156, which is now the load for this mode. The primary amplifiers 112, 114 may then be used as an auxiliary amplifier 150 for this mode by feeding the desired auxiliary amplifier drive signal into the unused input port of the primary amplifier's input quadrature splitter 102. This raises the possibility that both modes may be used at the same time to amplify two signals and deliver them to two loads.

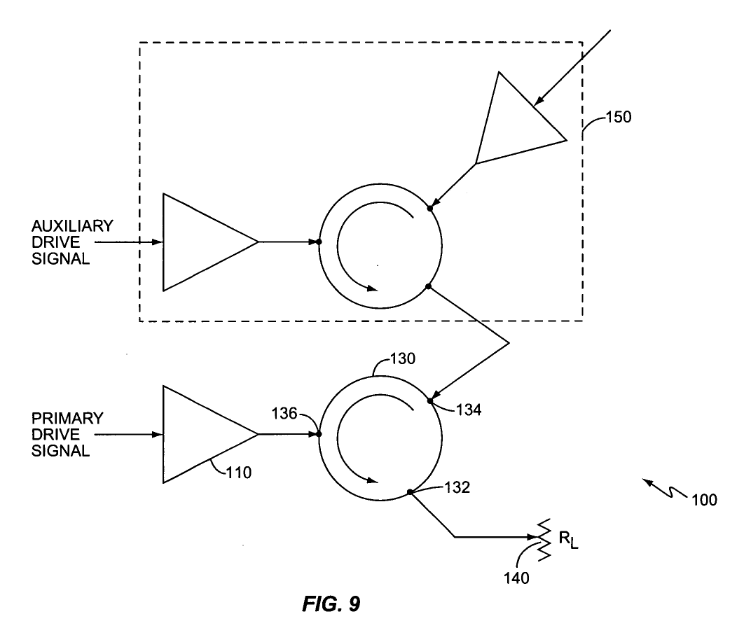

Alternatively, the construction of the auxiliary amplifier 150 may be extended by recursive applications of the inventive principle to arrive at a chain coupling of auxiliary amplifiers 150, which become progressively smaller, as shown in FIG. 9. The gain in efficiency is however small, and merely obviates the efficiency dip to 75% shown in FIG. 4A between 2Pₘₐₓ and 8Pₘₐₓ, and flattens it to a constant 78% across this range. Auxiliary amplifier 150 may also deliver higher efficiencies than conventional class B amplifiers when driven hard into saturation using harmonic filtering to select only the wanted fundamental component, as described in more detail in U.S. patent application Ser. No. 09/730,791 to Applicant filed 7 Dec. 2000 and entitled “Harmonic Matching Network Design for a Saturated Amplifier,” which is hereby incorporated by reference herein. It will be appreciated by those skilled in the art that the auxiliary amplifier configurations of FIGS. 8 and 9 are also applicable to the amplifier circuits 100 of FIGS. 6 and 2, respectively.

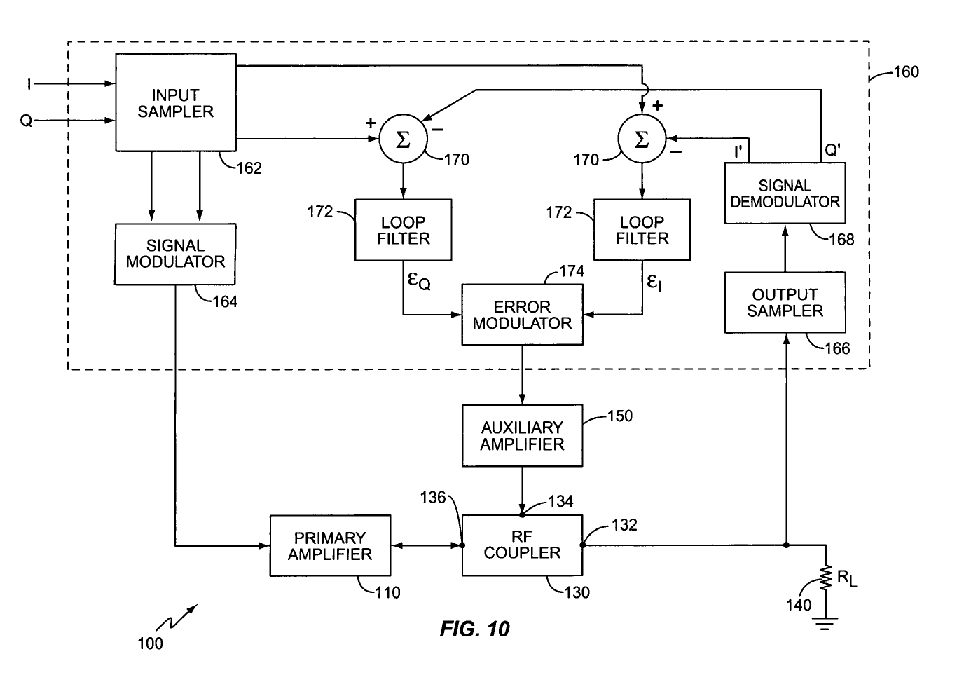

FIG. 10 shows an exemplary signal generator 160 that generates the desired drive signals for the amplifier circuit 100. Signal generator 160 comprises an input RF sampler 162, a signal modulator 164, an output RF sampler 166, a signal demodulator 168, comparators 170, loop filters 172, and error modulator 174. Input I, Q waveforms are applied to signal modulator 164, i.e., a quadrature modulator, as is well known. The modulated signal then drives primary amplifier 110, which may comprise the pair of quadrature coupled amplifiers 112, 114 as in FIG. 2, or a single amplifier 110, as in FIG. 6. Primary amplifier 110 faithfully amplifies the modulated signal until the primary amplifier i 10 approaches saturation, at which point the output of primary amplifier 110 may start to under represent the desired amplitude due to the saturation.

Output RF sampler 166, i.e., a -30dB directional coupler, samples the actual amplifier output to the load 140. The output signal sample is then demodulated back to the complex baseband by signal demodulator 168, i.e., a quadrature demodulator, to produce I′, Q′ signals. Signal demodulator 168 uses the same local oscillator signals (cos(wt), sin(wt)) as signal modulator 164 apart from a possible deliberate phase shift designed to match the phase shift through primary amplifier 110 and RF coupler 130. Thus, the output of demodulator 168 (I′, Q′) should match the desired I, Q input signals if the output to the load 140 is a faithful amplification of the original I, Q input.

Comparators 170 subtract the demodulated I′, Q′ signals from samples of the original I, Q signals provided by input sampler 162 to obtain error signals ε_{Q} and ε_{I}, which represent the error between the desired I, Q signals and the achieved I′, Q′ signals. Loop filters 172, which may typically be integrators, filter the error signals and apply the error signals to error modulator 174. Error modulator 174 generates a drive signal for auxiliary amplifier 150 that corrects the error by causing auxiliary amplifier 150 to contribute to the load 140 if the output power is too low due to the primary amplifier 110 either approaching saturation or arriving at saturation. With this feedback arrangement, no special waveform generation algorithm for the auxiliary amplifier 150 is needed; if desired however, the expected drive waveform for auxiliary amplifier 150 can be added to the output of filters 172. As a result, the feedback loop only needs to generate a correction to the “guess” at the correct waveform rather than having to provide the full waveform.

The arrangement of FIG. 10 is called a Cartesian loop because it resolves the controlled RF signal into X and Y (I, Q) or Cartesian coordinates. It is also possible to construct polar loops in which the RF signal is controlled in its amplitude or phase component or both.

A Cartesian loop may also be constructed without modulators and demodulators using the signal generator 180 shown in FIG. 1l. Signal generator 180 includes an input RF sampler 182, an output RF sampler 184, a comparator 186, and a loop filter 188. In FIG. 11, comparator 186 subtracts a sample of the RF output taken by output RF sampler 184 from a sample of the desired signal, taken by input RF sampler 182. Loop filter 188 then filters the error signal and auxiliary amplifier 150 corrects the error, as discussed above.

While the above uses comparators to generate the error signal(s), there are many alternative ways to obtain this error signal. For example, the sample of the desired signal may be input to a terminated port of output RF sampler 184 such that the desired difference signal is formed in and output from output RF sampler 184. Other methods may include using a matched 180° hybrid junction to combine the input and output samples with the desired subtractive phase relationship. The line lengths between the units are set to achieve the correct subtractive phase relationship. Because this phase relationship is difficult to maintain over a very large band of frequencies, loop filter 188 reduces the gain outside the band of interest. In FIG. 11, this band limitation may be provided by making loop filter 188 a single pole, narrow bandpass filter, such as a high-Q resonator. The loop filter 188 allows errors within the band of interest to be amplified with high gain while reducing the loop gain out of band to less than unity before the phase relationships change from stable negative feedback to unstable positive feedback.

The present invention may be implemented in a radio transceiver of a wireless terminal in a wireless communication system. Exemplary wireless terminals include base stations, mobile terminals, etc. An exemplary transceiver 300 is shown in FIG. 12. Transceiver 300 includes a transmitter 310 for transmitting radio communication signals to one or more wireless terminals in the wireless communication system via antenna 320, a receiver 330 for receiving radio communication signals from one or more wireless terminals via antenna 320, and the amplifier circuit 100 of FIG. 1. As described above, amplifier circuit 100 provides efficient linear amplification of signals transmitted to one or more wireless terminals by transmitter 310.

There are several advantages to the above described amplifier circuit 100. For example, because the auxiliary amplifier 150 is not directly connected to the load 140, auxiliary amplifier 150 does not contribute to the losses of the amplifier circuit 100. This also obviates the need to tune auxiliary amplifier 150 to present a high impedance to the output of the primary amplifier 110. As a result, the primary amplifier 110 may be readily used at microwave frequencies. Further, the amplifier circuit 100 may be designed for devices with, for example, normal 50 ohm outputs and inputs. As a result, the amplifier circuits 100 of the present invention may be tested using conventional test equipment.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

1. An amplifying circuit comprising:
at least one primary amplifier for providing power to a load;
at least one auxiliary amplifier for generating an artificial reflection signal; and
a coupler connecting the primary amplifier to the load, the coupler comprising:
a load port connected to the load;
a primary port connected to an output of the primary amplifier; and
an auxiliary port connected to an output of the auxiliary amplifier such that the artificial reflection signal changes an apparent impedance of the load as seen by the primary amplifier at the primary port.

2. The amplifying circuit of claim 1 wherein the coupler comprises a circulator.

3. The amplifying circuit of claim 1 comprising first and second primary amplifiers driven in quadrature and wherein the coupler comprises a quadrature coupler.

4. The amplifying circuit of claim 3 wherein the coupler comprises first and second primary ports connected respectively to the outputs of the first and second primary amplifiers.

5. The amplifying circuit of claim 4 wherein the quadrature coupler combines output signals present at the first and second primary amplifiers such that the signals add constructively at the load port and add destructively at the auxiliary port.

6. The amplifying circuit of claim 1 wherein the power at the load comprises a combination of a primary power provided by the primary amplifier and an auxiliary power provided by the auxiliary amplifier.

7. The amplifying circuit of claim 1 further comprising a first signal generator for generating a first modulated input signal for the primary amplifier and a second signal generator for generating a second modulated input signal for the auxiliary amplifier, wherein the first and second modulated input signals drive the primary and auxiliary amplifiers, respectively, such that a signal at the load is an amplified version of a desired modulated signal.

8. The amplifying circuit of claim 7 wherein the first modulated input signal is proportional to the desired modulated signal by a first proportionality constant when the auxiliary amplifier is disabled, and wherein the first modulated input signal is proportional to the desired modulated signal by a second proportionality constant when the auxiliary amplifier is enabled.

9. The amplifying circuit of claim 7 wherein the second signal generator comprises:
a comparator for comparing a portion of the signal at the load to the desired modulated signal to obtain an error signal; and
a loop filter for filtering said error signal to produce the second modulated input signal.

10. The amplifying circuit of claim 9 wherein the loop filter comprises a single-pole high-Q resonator.

11. The amplifying circuit of claim 7 wherein the first signal generator combines first I and Q modulation waveforms with cosine and sine wave radio frequency carrier signals, respectively, to produce the first modulated input signal, and wherein the second signal generator combines second I and Q modulation waveforms with the cosine and sine wave radio frequency carrier signals, respectively, to produce the second modulated input signal.

12. The amplifying circuit of claim 11 further comprising:
a demodulator to quadrature demodulate a portion of the signal at the load to produce output I and Q modulation waveforms;
comparators to subtract the output I and Q modulation waveforms from the first I and Q waveforms to obtain error I and Q modulation waveforms; and
loop filters to filter the error I and Q modulation waveforms to produce the second modulated input signal.

13. An amplifying circuit comprising:
at least one primary amplifier for supplying an output signal to a load; and
at least one auxiliary amplifier for injecting an artificial reflection signal into an output of the primary amplifier such that the artificial reflection signal changes an apparent impedance of the load as seen by the primary amplifier;
wherein the artificial reflection signal has a predetermined phase difference as compared to the output signal supplied to the load.

14. The amplifying circuit of claim 13 wherein the output signal supplied to the load comprises a combination of a primary power provided by the primary amplifier and an auxiliary power provided by the auxiliary amplifier.

15. The amplifying circuit of claim 13 further comprising a first signal generator for generating a first modulated input signal for the primary amplifier and a second signal generator for generating a second modulated input signal for the auxiliary amplifier, wherein the first and second modulated input signals drive the primary and auxiliary amplifiers, respectively, such that the output signal supplied to the load is an amplified version of a desired modulated signal.

16. The amplifying circuit of claim 15 wherein the first modulated input signal is proportional to the desired modulated signal by a first proportionality constant when the auxiliary amplifier is disabled, and wherein the first modulated input signal is proportional to the desired modulated signal by a second proportionality constant when the auxiliary amplifier is enabled.

17. The amplifying circuit of claim 15 wherein the second signal generator comprises:
a comparator for comparing a portion of the output signal supplied to the load to the desired modulated signal to obtain an error signal; and
a loop filter for filtering said error signal to produce the second modulated input signal.

18. The amplifying circuit of claim 17 wherein the loop filter comprises a single-pole high-Q resonator.

19. The amplifying circuit of claim 15 wherein the first signal generator combines first I and Q modulation waveforms with cosine and sine wave radio frequency carrier signals, respectively, to produce the first modulated input signal, and wherein the second signal generator combines second I and Q modulation waveforms with the cosine and sine wave radio frequency carrier signals, respectively, to produce the second modulated input signal.

20. The amplifying circuit of claim 19 further comprising:
a demodulator to quadrature demodulate a portion of the output signal supplied to the load to produce output I and Q modulated waveforms;
comparators to subtract the output I and Q modulated waveforms from the first I and Q modulated waveforms to obtain error I and Q modulated waveforms; and
loop filters to filter the error I and Q modulated waveforms to produce the second modulated input signal.

21. The amplifying circuit of claim 13 further comprising a coupler connecting the primary amplifier to the load, the coupler comprising:
a load port connected to the load;
a primary port connected to an output of the primary amplifier; and
an auxiliary port connected to an output of the auxiliary amplifier such that the artificial reflection signal changes an apparent impedance of the load as seen by the primary amplifier at the primary port.

22. The amplifying circuit of claim 21 wherein the coupler comprises a circulator.

23. The amplifying circuit of claim 21 comprising first and second primary amplifiers driven in quadrature and wherein the coupler comprises a quadrature coupler.

24. A method of efficient linear amplification comprising:
connecting a load to a load port of an RF coupler;
generating an output signal at an output of at least one primary amplifier;
generating an artificial reflection signal at an output of at least one auxiliary amplifier;
connecting the output of the primary amplifier to a primary port of the RF coupler to provide power to the load; and
connecting the output of the auxiliary amplifier to an auxiliary port of the RF coupler such that the artificial reflection signal changes an apparent impedance of the load as seen by the primary amplifier.

25. The method of claim 24 comprising driving first and second primary amplifiers in quadrature.

26. The method of claim 25 wherein connecting the output of the primary amplifier to the primary port of the RF coupler comprises connecting the output of the primary amplifier to at least one primary port of a quadrature coupler.

27. The method of claim 26 comprising connecting first and second primary ports, respectively, to the outputs of the first and second amplifiers.

28. The method of claim 27 further comprising combining signals present at the outputs of the first and second amplifiers, respectively, such that the signals add constructively at the load port and add destructively at the auxiliary port.

29. The method of claim 24 wherein connecting the output of the primary amplifier to the primary port of the RF coupler to provide power to the load comprises connecting the output of the primary amplifier to the primary port such that the power provided to the load comprises a combination of primary power provided by the primary amplifier and auxiliary power provided by the auxiliary amplifier.

30. The method of claim 24 further comprising:
generating a first modulated input signal for the primary amplifier;
generating a second modulated input signal for the auxiliary amplifier; and
driving the primary and auxiliary amplifiers with the first and second modulated input signals, respectively, such that a signal at the load is an amplified version of a desired modulated signal.

31. The method of claim 30 wherein generating the first modulated input signal for the primary amplifier comprises:
generating the first modulated input signal by weighting the desired modulated signal by a first proportionality constant when the auxiliary amplifier is disabled; and
generating the first modulated input signal by weighting the desired modulated signal by a second proportionality constant when the auxiliary amplifier is enabled.

32. The method of claim 30 wherein generating the second modulated input signal for the auxiliary amplifier comprises:
comparing a portion of the signal at the load to the desired modulated signal to obtain an error signal; and
filtering the error signal to generate the second modulated input signal.

33. The method of claim 30 wherein generating the first modulated input signal for the primary amplifier comprises combining first I and Q modulation waveforms with cosine and sine radio frequency carrier signals, respectively, and wherein generating the second modulated input signal for the auxiliary amplifier comprises combining second I and Q modulation waveforms with the cosine and sine wave radio frequency carrier signals, respectively.

34. The method of claim 33 further comprising:
demodulating a portion of the signal at the load to produce output I and Q modulation waveforms;
subtracting the output I and Q modulation waveforms from the first I and Q modulation waveforms to generate error I and Q waveforms; and
filtering the error I and Q modulation waveforms to generate the second modulated input signal.

35. A radio transceiver comprising:
a transmitter for transmitting radio communication signals to at least one wireless terminal in a wireless communication system;
a receiver for receiving radio communication signals from wireless terminals in a wireless communication system; and
an amplifier circuit for amplifying signals transmitted by transmitter comprising:
at least one primary amplifier for providing power to a load antenna;
at least one auxiliary amplifier for generating an artificial reflection signal; and
a coupler connecting the primary amplifier to the load, the coupler comprising:
a load port connected to the load;
a primary port connected to an output of the primary amplifier; and
an auxiliary port connected to an output of the auxiliary amplifier such that the artificial reflection signal changes an apparent impedance of the load as seen by the primary amplifier at the primary port.

36. The radio transceiver of claim 35 wherein the coupler comprises a circulator.

37. The radio transceiver of claim 35 comprising first and second primary amplifiers driven in quadrature and wherein the coupler comprises a quadrature coupler.

38. The radio transceiver of claim 37 wherein the quadrature coupler comprises first and second primary ports connected respectively to the outputs of the first and second primary amplifiers.

39. The radio transceiver of claim 38 wherein the quadrature coupler combines output signals present at the first and second primary amplifiers such that the signals add constructively at the load port and add destructively at the auxiliary port.
